(19) United States
(12) Patent Application Publication
(10) Pub. No.: US 2025/0201666 A1
(43) Pub. Date: Jun. 19, 2025

(54) Power Module For An Electronic Computing Device

(71) Applicant: Siemens Aktiengesellschaft, München (DE)

(72) Inventors: Jörg Strogies, Berlin (DE); Bernd Müller, Falkenberg (DE); Matthias Heimann, Potsdam (DE); Lisa Stencel, Berlin (DE); Thomas Bigl, Herzogenaurach (DE); Alexander Hensler, Gerhardshofen (DE); Markus Pfeifer, Nürnberg (DE)

(73) Assignee: Siemens Aktiengesellschaft, München (DE)

(21) Appl. No.: 18/980,080

(22) Filed: Dec. 13, 2024

(30) Foreign Application Priority Data
Dec. 15, 2023 (EP) 23217186.8

(51) Int. Cl. H01L 23/467; H01L 23/36

(52) U.S. Cl. CPC H01L 23/467; H01L 23/36

(57) ABSTRACT

Various embodiments of the teachings herein include a power module for an electronic computing device. An example includes: a power chip generating heat during operation and a first vapor chamber device on one side of the power chip. The power chip and the first vapor chamber device make up a common surface-mountable component.

### CROSS-REFERENCE TO RELATED APPLICATIONS

This application claims priority to EP application Ser. No. 23217186.8 filed Dec. 15, 2023, the contents of which are hereby incorporated by reference in their entirety.

### TECHNICAL FIELD

The present disclosure relates to electronic computing. Various embodiments of the teachings herein include a power module for an electronic computing device, said power module comprising at least one power chip which generates heat during operation, the power module including a surface-mountable component.

### BACKGROUND

Power electronic components are increasingly characterized by extreme power densities. This entails the challenge of an effective dissipation of the resulting thermal losses. In the wake of this development, single-sided cooling solutions are increasingly coming up against their application limits.

Currently, the issues arising with single-sided cooling are resolved by means of appropriate configuration. However, this conflicts with the structural and technological requirements leading toward miniaturized components. Generally, heat dissipation is substantially improved by means of dual-sided cooling concepts. The thermal flow paths necessary for this in a dual-sided arrangement are realized using corresponding heatsinks and lead to considerable limitations in terms of the overall system design and in particular also allow the use of highly miniaturized components and the combination of power and logic functions on common motherboards only at the expense of substantial extra investment of resources.

### SUMMARY

The teachings of the present disclosure provide power modules which can be easily produced and nonetheless enable reliable dissipation of heat from the power chip to be realized. Various embodiments of the teachings herein include a power module (12) for an electronic computing device, said power module (12) comprising at least one power chip (18) which generates heat during operation, wherein the power module (12) is embodied as a surface-mountable component (20), characterized in that at least one first vapor chamber device (22) is embodied on one side of the power chip (18), wherein the power chip (18) and at least the first vapor chamber device (22) are embodied as a common surface-mountable component (20).

In some embodiments, the power module (12) is embodied as a quad flat no-leads package component.

In some embodiments, the power chip (18) is embodied in a substantially cuboidal shape.

In some embodiments, a second vapor chamber device (24) is arranged opposite the first vapor chamber device (22) on the power chip (18).

In some embodiments, the power module (12) comprises a third vapor chamber device on a third side of the power chip (18).

In some embodiments, the power module (12) comprises a fourth vapor chamber device on a fourth side of the power chip (18).

In some embodiments, the power module (12) comprises at least one fifth vapor chamber device (38) on a top side (26) of the power chip (18).

In some embodiments, the power chip (18) is arranged at a joining zone (36) with an underside of the power chip (18), wherein the power chip (18) and the joining zone (36) are embodied as a surface-mountable component (20).

In some embodiments, the power module (12) comprises a metallic component (38) and the joining zone (36) is connected to the metallic component (38).

In some embodiments, the metallic component (38) is made of copper.

In some embodiments, the metallic component (38) is connected to an insulating layer (40).

In some embodiments, the insulating layer (40) is made of a ceramic material.

In some embodiments, the insulating layer (40) is connected to a further metallic component (42).

As another example, some embodiments include an arrangement (10) comprising a heatsink (14) and having a power module (12) as described herein.

In some embodiments, the power module (12) is coupled to a printed circuit board (16) on a side of the arrangement (10) facing away from the heatsink (14).

### BRIEF DESCRIPTION OF THE DRAWINGS

Further features and feature combinations of the teachings herein are apparent from the figures and the description thereof as well as from the claims. In particular, further embodiment variants do not necessarily have to include all the features of one of the claims. Further embodiments may have features or feature combinations that are not cited in the claims.

FIG. 1 shows a schematic side view of an example arrangement comprising a power module incorporating teachings of the present disclosure;

FIG. 2 shows a schematic side view of an example power module incorporating teachings of the present disclosure;

FIG. 3 shows a further schematic side view in an exploded representation incorporating teachings of the present disclosure; and

FIG. 4 shows a further schematic side view in an exploded representation incorporating teachings of the present disclosure.

### DETAILED DESCRIPTION

Some examples of the teachings herein include a power module for an electronic computing device, said power module comprising at least one power chip which generates heat during operation, the power module being embodied as a surface-mountable component. At least one first vapor chamber device is disposed on one side of the power chip, the power chip and the vapor chamber device being embodied as a common surface-mountable component.

This arrangement combines features of the former single-sided and dual-sided cooling concepts by achieving a high level of thermal performance by virtue of multiple heat dissipation paths and nonetheless allowing simple system integration. The use of the vapor chamber device, also referred to as a vapor chamber, additionally enables a substantially more efficient heat splay and consequently a more homogeneous heat distribution and faster heat dissipation in contrast to passive materials. To achieve a miniaturized mode of construction delivering a high yield in the context of the manufacturing process, it is necessary in the prior art to utilize intermediate wiring substrates, in particular layers known as interposers. This structure is subsequently encapsulated by way of underfilling in order to be combined as an autonomous, electrically measurable unit in a multiple implementation on a motherboard. The concepts are combined, in particular that a semi-dual-sided cooling solution using ultrathin vapor chamber devices is combined with what is termed a molded surface-mountable component.

The surface-mountable component may be called a surface-mount device (SMD). These SMD components are surface-mounted components, wherein the wired components are not wire terminal leads but can be soldered directly onto a printed circuit board by means of solderable terminal pads or pins. The associated method is also referred to as surface-mount technology (SMT). This is a high-performance manufacturing methodology which enables a multiplicity of elements to be built.

To shield against environmental influences but also to provide thermomechanical stabilization and to ensure electrical insulation in the presence of high electrical voltages, encapsulations can be realized by molding. By sealing the structure by means of processes such as compression molding or transfer molding it is possible to dispense with the use of intermediate wiring substrates, in particular the interposers, and with the use of underfilling since the surface-mountable component is already considered as an autonomous, electrically measurable, and easy-to-handle unit. This means a simplification of the structure by eliminating the interposer on the one hand and on the other hand an increase in process efficiency since encapsulation by underfilling is generally time-intensive in the case of larger installation spaces. For the reasons cited, a considerable potential for improved productivity is realized compared with the previous concept. This combines the advantageous and efficient dissipation of heat from the power chip by way of the lateral surfaces with consolidation into a miniaturized surface-mounted device.

The combination of semi-dual-sided cooling and the implementation of this in a highly miniaturized SMD package may greatly simplify the overall construction and the manufacturing steps associated therewith. As a result of the functional integration of the miniaturized vapor chamber device it is simultaneously possible with said construction elements to realize the function of the electrical connection and the function of the SMD pads at the externally accessible regions. Furthermore, the mode of construction permits highly efficient encapsulation methods by means of molding processes. At least a proportion of the manufacturing steps may also be performed in the panelization cluster.

In some embodiments, the power module is embodied as a quad flat no-leads package component. This is in particular what is termed a QFN pack. This is to be regarded in particular as a subgroup of the SMD components. The quad flat no-leads packages are also referred to as micro lead frame (MLF) packages and are a chip package format for integrated circuits in common use in the electronics industry. The designation in this case comprises different sizes of IC (integrated circuit) packages, all of which are soldered as surface-mountable components onto printed circuit boards. As significant features in contrast to the quad flat package (QFP), for example, the electrical terminals, in particular the pins, do not substantially protrude at the sides beyond the dimensions of the plastic enclosure but are integrated on a level into the underside of the package in the form of partially tinned copper terminals. This enables the requisite space on the printed circuit board to be reduced and a higher packing density to be achieved.

In some embodiments, the power chip is embodied in a substantially cuboidal shape. This enables a simple shape to be provided for the power chip. Furthermore, the power chip then has substantially six sides and heat can be dissipated from it via different sides, for example.

In some embodiments, a second vapor chamber device is arranged opposite the first vapor chamber device on the power chip. This enables heat to be dissipated via a second side of the power chip. This leads to a power increase for the power chip, thereby enabling in particular a higher performance to be provided by the power chip.

In some embodiments, the power module has a third vapor chamber device on a third side of the power chip. In this case the third side can be embodied for example at right angles to the side having the first vapor chamber device. A third vapor chamber device can thus be provided, thereby enabling an even higher degree of heat dissipation to be achieved.

In some embodiments, the power module comprises a fourth vapor chamber device on a fourth side of the power chip. In this case the fourth side is preferably arranged opposite the third side, for example. As a result, the power module can be cooled accordingly by way of four sides, thereby enabling an increased level of performance to be achieved.

In some embodiments, the power module comprises at least one fifth vapor chamber device on a top side of the power chip. In particular, appropriate electronic connecting elements, such as, for example, a gate terminal or a source terminal, can be provided on a top side of the power chip, for example. In particular, gate and source can then be cooled by means of different vapor chamber devices in each case since it is then necessary in particular for these to be electrically insulated from one another. The individual components can consequently be cooled in addition via the top side as appropriate, thereby enabling an improved dissipation of heat from the power module or power chip to be realized.

In some embodiments, the power chip is arranged at a joining zone with an underside of the power chip, the power chip and the joining zone being embodied as a surface-mountable component. A surface-mountable component can therefore be provided in a simple manner.

In some embodiments, the power module comprises a metallic component and the joining zone is connected to the metallic component. The metallic component can therefore be embodied to absorb the heat transfer from the first vapor chamber device for example and for example to dissipate the heat from the power chip. In particular, the metallic component is then embodied in the direction of a heatsink of an arrangement with the power module, thereby enabling a thermal transfer path to the heatsink to be realized.

In some embodiments, the metallic component is made of copper. Copper forms a metallic component having a very high coefficient of thermal conductivity. Furthermore, copper is already well-established. Dissipation of heat from the power chip can therefore be achieved in a simple manner.

In some embodiments, the metallic component is connected to an insulating layer. The insulating layer serves to ensure that the metallic component is electrically insulated. Corresponding electrical flashovers from a cooling side to the power chip can consequently be prevented. Short-circuits can thus be prevented, thereby enabling reliable operation of the power module to be achieved.

In some embodiments, the insulating layer is made of a ceramic material. Ceramic materials in particular have a high coefficient of thermal conductivity as well as a high electrical insulation capability. Accordingly, both an electrical insulation and dissipation of heat from the metallic component in the direction of a heatsink can be achieved.

In some embodiments, the insulating layer is connected to a further metallic component. In this case the further metallic component may for example likewise be made of copper. The further metallic component can in turn then be in contact with the heatsink. Accordingly, a heat dissipation path from the power module in the direction of the heatsink can reliably be achieved.

In some embodiments, an arrangement comprises a heatsink and a power module as described herein.

In some embodiments, the power module is coupled to a printed circuit board on a side of the arrangement facing away from the heatsink. It is then possible in particular to accomplish appropriate connections of the power module via the printed circuit board.

In some embodiments, there is an electronic computing device comprising at least one arrangement as described herein. Teachings related to embodiments of the power module are to be regarded as applicable to the arrangement as well as to the electronic computing device.

A computing unit includes a data processing device containing a processing circuit. Accordingly, the computing unit is able to process data for performing computational operations. These may also include operations for performing indexed accesses to a data structure, a look-up table (LUT) for example.

The computing unit may contain one or more computers, one or more microcontrollers and/or one or more integrated circuits, for example one or more application-specific integrated circuits (ASICs), one or more field-programmable gate arrays (FPGAs) and/or one or more single-chip systems (SoC: system on a chip). The computing unit may also contain one or more processors, for example one or more microprocessors, one or more central processing units (CPUs), one or more graphics processing units (GPUs) and/or one or more signal processors, in particular one or more digital signal processors (DSPs). The computing unit may also include a physical or virtual cluster of computers or other of the cited units. In some embodiments, the computing unit contains one or more hardware and/or software interfaces and/or one or more memory units.

A memory unit may include a volatile data memory, for example as a dynamic random access memory (DRAM) or a static random access memory (SRAM), or as a non-volatile data memory, for example as a read-only memory (ROM), as a programmable read-only memory (PROM), as an erasable programmable read-only memory (EPROM), as an electrically erasable programmable read-only memory (EEPROM), as a flash memory or flash EEPROM, as a ferroelectric random access memory (FRAM), as a magnetoresistive random access memory (MRAM) or as a phase-change random access memory (PCRAM).

Independent of the grammatical term usage, individuals with male, female, or other gender identities are included within the term.

The invention is explained in more detail below with reference to actual exemplary embodiments and associated schematic drawings. Like or functionally like elements may be labeled with the same reference signs in the figures. The description of like or functionally like elements may not necessarily be repeated with regard to different figures.

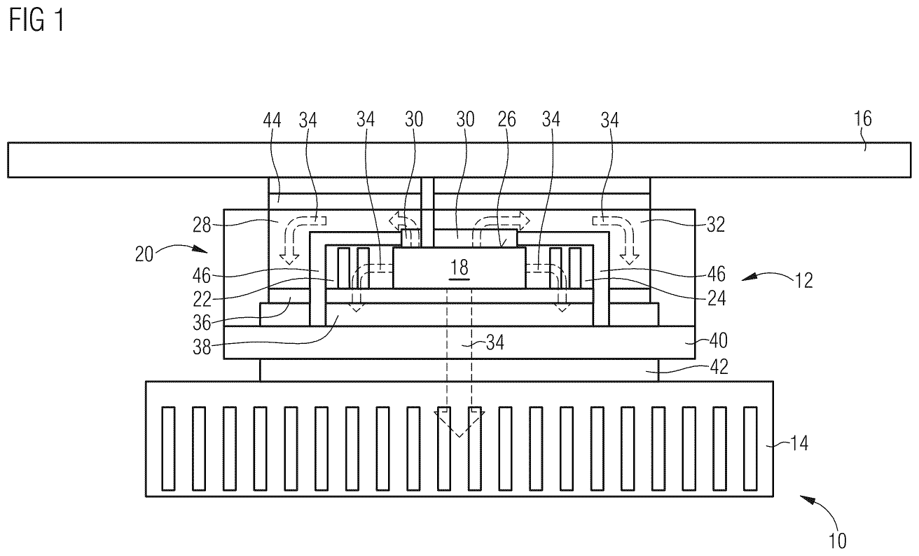

FIG. 1 shows a schematic side view of an example arrangement 10. The arrangement 10 comprises at least one power module 12, a heatsink 14 and a printed circuit board 16. FIG. 1 shows in particular the power module 12 for an electronic computing device (not shown). In this instance the power module 12 comprises at least one power chip 18 which generates heat during operation. The power module 12 comprises a surface-mountable component 20.

At least one first vapor chamber device 22 is provided on one side of the power chip 18, the power chip 18 and the first vapor chamber device 22 being embodied as a common surface-mountable component 20. The power module 12 is embodied as a quad flat no-leads package component.

FIG. 1 further shows that the power chip 18 has a substantially cuboidal shape. A second vapor chamber device 24 is arranged opposite the first vapor chamber device 22 on the power chip 18. Furthermore, the power module 12 may comprise a third vapor chamber device on a third side of the power chip 18. In the present embodiment, the third side is located in the drawing plane. Moreover, the power module 12 may comprise a fourth vapor chamber device on a fourth side of the power chip 18, the fourth side being situated in turn in front of the drawing plane.

In particular, FIG. 1 further shows that the power module 12 may comprise at least one fifth vapor chamber device 28 on a top side 26 of the power chip 18. In the present example, corresponding electronic terminals 30 in particular are arranged on the top side 26. For example, the terminals 30 may be source and gate terminals. These should in particular be electronically or electrically separated from one another. It may therefore also be provided that a sixth vapor chamber device 32 is provided on the top side 26. Furthermore, the components 30 are likewise electrically separated via the vapor chamber devices 28, 32.

FIG. 1 further shows corresponding heat dissipation paths 34, which in the present example are represented by arrows. The power chip 18 is arranged at a joining zone 36 with an underside of the power chip 18, the power chip 18 and the joining zone 36 includes a surface-mountable component.

In some embodiments, the power module 12 comprises a metallic component 38 and the joining zone 36 is connected to the metallic component 38. In this case the metallic component 38 may be made of copper, for example. In some embodiments, the metallic component 38 is connected to an insulating layer 40. In this case the insulating layer 40 may be made of a ceramic material, for example. The insulating layer 40 may additionally be connected to a further metallic component 42, which for example is likewise made of copper.

FIG. 1 shows that the power module 12 can be attached to the printed circuit board 16 via a soldered/sintered joint 44, for example. Further shown is a spatial and electrical separation 46 which in particular spatially and electrically separates the individual vapor chamber devices 22, 24, 28, 32 from one another.

Overall, therefore, FIG. 1 shows that the proposed concept once again combines the advantages of the semi-dual-sided cooling solution using ultrathin vapor chamber devices 22, 24, 28, 32 with the advantages of a molded quad flat no-leads package. To shield against environmental influences but also to provide thermomechanical stabilization and to ensure electrical insulation in the presence of high electrical voltages, encapsulations can be realized by means of molding. By sealing the structure by means of processes such as compression or transfer molding it is possible to dispense with the use of intermediate wiring substrates, in particular interposers, and with the use of underfilling since the QFN package is already considered as an autonomous, electrically measurable and easy-to-handle unit. This means a simplification of the structure by eliminating the interposer on the one hand and on the other hand an increase in process efficiency since the encapsulation by underfill generally requires a larger installation space and is time-intensive. For the reasons cited, a considerable potential for improved productivity may be realized compared with the previous concept.

The proposed concept in this case combines the advantages of efficient dissipation of heat from the power chip 18 via its side surfaces and top sides and consolidation in a miniaturized surface-mounted device (SMD), e.g. in the form of a QFN package.

In this arrangement, the vapor chamber devices 22, 24, 28, 32 may be embodied as separate vapor chamber devices 22, 24, 28, 32. In some embodiments, the vapor chamber devices 22, 24, 28, 32 may be a common vapor chamber device 22, 24, 28, 32 and form for example a frame-shaped structure around the power chip 18.

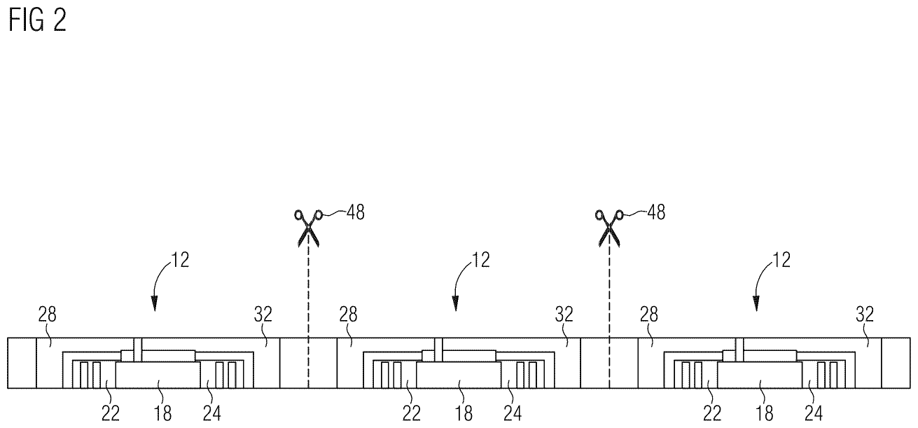

FIG. 2 shows a schematic view of a plurality of power modules 12 which are fabricated together and can be separated from one another by sawing 48, for example. In particular, FIG. 2 shows that the cooling arrangement can be implemented in a highly miniaturized package in the form of a QFN. In this case various paths to efficient processing are conceivable in principle. Here, FIG. 2 shows a possible approach in the prefabrication of the chip module, wherein the latter already includes the lateral and top-side vapor chamber devices 22, 24, 28, 32 and their connections to the power chip 18. It is advantageous in this context to fabricate a larger panel of molded chip modules since the collective molding in particular offers technological advantages. The chip modules can be singulated from the panel by means of sawing 48.

In this process it can happen that following their completion the joints to the ceramic substrate cause a residual gap between substrate surface and sealing compounds. This residual gap must subsequently be closed either by means of a suitable material or the design must be laid out geometrically taking said residual gap into account.

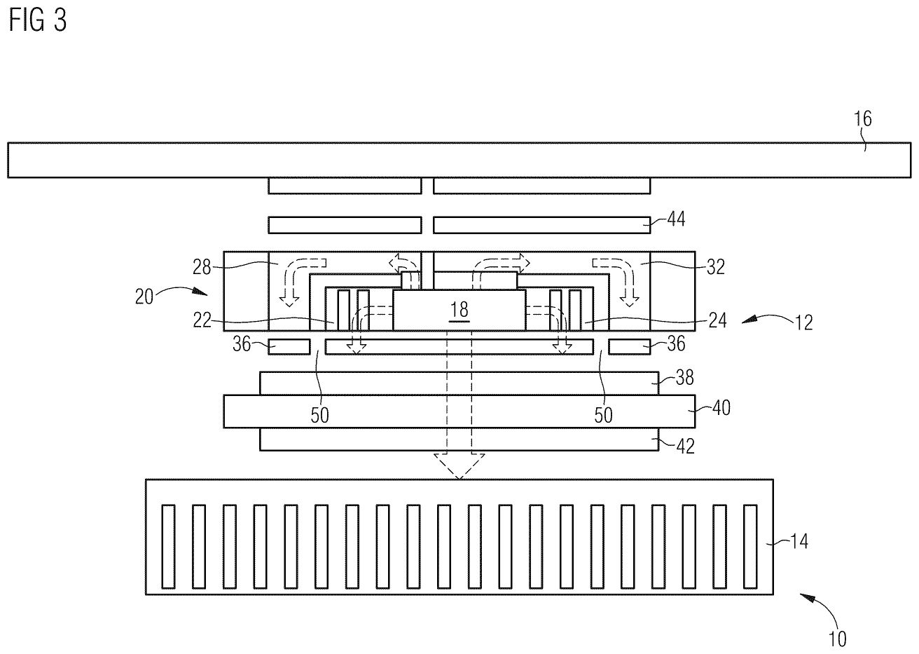

FIG. 3 shows a schematic side view of an embodiment of the arrangement 10, in an exploded representation. Shown here is the approach to the closing of the residual gap, wherein the integration can be realized by way of a joining process during sintering, wherein for example prepregs or polysiloxane films can be applied simultaneously. In this case there is shown in the following exemplary embodiment the surface-mountable component 20, as illustrated in FIG. 2. A residual gap 50 within the joining zone 36 is also shown.

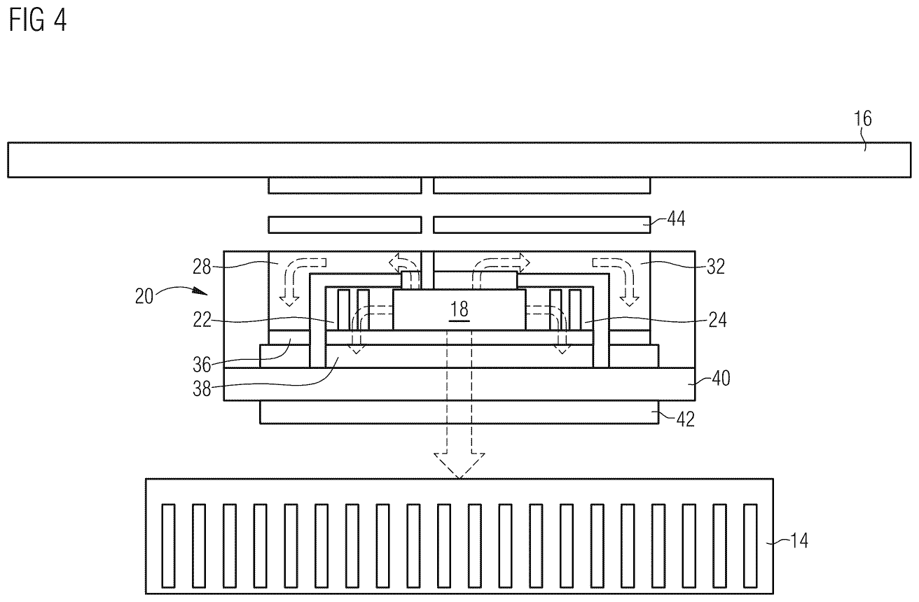

FIG. 4 shows a further schematic side view of an embodiment of the power module 12 or of the arrangement 10. It is shown in this case that in the following exemplary embodiment the surface-mountable component 20 comprises both the chip structure from FIG. 2 and FIG. 3 and the joining zone 36, the metallic component 38, the insulating layer 40 and the further metallic component 42.

In particular, therefore, FIG. 4 shows a further possibility in the fabrication of the individual chip modules initially on the basis of the e.g. ceramic substrate. In this case the joining zones of the chip backsides, the chip top sides and the lateral attachment to the circumferential vapor chamber device 22, 24, 28, 32 would be implemented initially. Next, the arrangement is remolded, the mold cap adjoining the top side of the chip carrier substrate directly and without residual gap 50. With this variant, the mold tool would need to be of more complex design to allow panel fabrication, the challenge of the residual gap 50 being removed in return.

### LIST OF REFERENCE SIGNS

10 Arrangement
12 Power module
14 Heatsink
16 Printed circuit board
18 Power chip
20 Surface-mountable component
22 First vapor chamber device
24 Second vapor chamber device
26 Top side
28 Third vapor chamber device
30 Electronic terminals
32 Fourth vapor chamber device
34 Thermal path
36 Joining zone
38 Metallic component
40 Insulating layer
42 Further metallic component
44 Soldered/sintered joint
46 Electrical insulation
48 Sawing
50 Residual gap

1. A power module for an electronic computing device, the power module comprising:
a power chip generating heat during operation;
a first vapor chamber device on one side of the power chip;
wherein the power chip and the first vapor chamber device make up a common surface-mountable component.

2. The power module as claimed in claim 1, wherein the power module comprises a quad flat no-leads package component.

3. The power module as claimed in claim 1, wherein the power chip has a substantially cuboidal shape.

4. The power module as claimed in claim 3, further comprising a second vapor chamber device arranged opposite the first vapor chamber device on the power chip.

5. The power module as claimed in claim 3, further comprising a third vapor chamber device on a third side of the power chip.

6. The power module as claimed in claim 3, further comprising a fourth vapor chamber device on a fourth side of the power chip.

7. The power module as claimed in claim 3, further comprising a fifth vapor chamber device on a top side of the power chip.

8. The power module as claimed in claim 1, wherein the power chip is arranged at a joining zone with an underside of the power chip, wherein the power chip and the joining zone make up a surface-mountable component.

9. The power module as claimed in claim 8, wherein the power module comprises a metallic component and the joining zone is connected to the metallic component.

10. The power module as claimed in claim 9, wherein the metallic component comprises copper.

11. The power module as claimed in claim 9, wherein the metallic component is connected to an insulating layer.

12. The power module as claimed in claim 11, wherein the insulating layer comprises a ceramic.

13. The power module as claimed in claim 11, wherein the insulating layer is connected to a further metallic component.

14. An arrangement comprising:
a heatsink;
a power chip generating heat during operation; and
a first vapor chamber device on one side of the power chip;
wherein the power chip and the first vapor chamber device make up a common surface-mountable component.

15. The arrangement as claimed in claim 14, wherein the power module is coupled to a printed circuit board on a side of the arrangement facing away from the heatsink.
